(19) United States
(12) Patent Application Publication
(10) Pub. No.: US 2024/0204773 A1
(43) Pub. Date: Jun. 20, 2024

(54) CURRENT DRIVER

(71) Applicant: ROHM CO., LTD., KYOTO (JP)

(72) Inventors: TAKAHIRO KITAHARA, KYOTO (JP); KOJI SAITO, KYOTO (JP)

(21) Appl. No.: 18/218,260

(22) Filed: Jul. 5, 2023

(30) Foreign Application Priority Data
Jul. 7, 2022 (JP) 2022-109551

(51) Int. Cl. H03K 17/687; H03K 17/06; H03K 17/0814

(52) U.S. Cl. CPC H03K 17/687; H03K 17/063; H03K 17/08142

(57) ABSTRACT

The present disclosure provides a current driver, configured to supply a drive current to a load disposed between a terminal to which a drive voltage is applied and an output terminal. The current driver includes a first transistor and a second transistor, connected in series between the output terminal and a ground; and a control circuit, configured to control states of the first transistor and the second transistor. The first transistor is arranged at a potential side lower than the second transistor. The drive current is supplied to the load through the first transistor and the second transistor by turning on the first transistor and the second transistor. A first voltage and a second voltage are obtained by dividing an output terminal voltage applied to the output terminal using a plurality of resistors.

### TECHNICAL FIELD

The present disclosure relates to a current driver.

### BACKGROUND

A current driver serves as a circuit that supplies a drive current based on a drive voltage to a load. The current driver is connected to the load, and supplies the drive current to the load at necessary timings.

### PRIOR ART DOCUMENT

### Patent Publication

[Patent publication 1] Japan Patent Publication No. 2007-127912

### BRIEF DESCRIPTION OF THE DRAWINGS

FIG. 1 is an overall configuration diagram of a sensor system according to an embodiment of the present disclosure.

FIG. 2 is a circuit diagram of a drive circuit of a reference configuration.

FIG. 3 is a circuit diagram of a drive circuit according to a first embodiment of the embodiments of the present disclosure.

FIG. 4 is a diagram of a circuit for generating a gate signal of a drive transistor according to the first embodiment of the embodiments of the present disclosure.

FIG. 5 is a diagram of conditions of a drive circuit in a basic drive state according to the first embodiment of the embodiments of the present disclosure.

FIG. 6 is a circuit diagram of a drive circuit according to a second embodiment of the embodiments of the present disclosure.

FIG. 7 is a circuit diagram of a drive circuit according to a third embodiment of the embodiments of the present disclosure.

FIG. 8 is a diagram of conditions of a drive circuit in a standby state according to a fourth embodiment of the embodiments of the present disclosure.

FIG. 9 is a diagram of conditions of a drive circuit in a basic drive state according to the fourth embodiment of the embodiments of the present disclosure.

FIG. 10 is a diagram of conditions of a drive circuit in a power-off state according to the fourth embodiment of the embodiments of the present disclosure.

FIG. 11 is a diagram of conditions of a drive circuit in a power interrupted state according to the fourth embodiment of the embodiments of the present disclosure.

### DETAILED DESCRIPTION OF THE EMBODIMENTS

Details of examples of the embodiments of the present disclosure are provided with the accompanying drawings below. In the reference drawings, the same portions are denoted by the same numerals or symbols, and repeated description related to the same portions is in principle omitted. Moreover, in the present application, in order to keep the description simple, by means of recording numerals or symbols of reference information, signals, physical quantities, functional units, circuits, elements or parts, names of information, signals, physical quantities, functional units, circuits, elements or parts corresponding to the numerals or symbols are sometimes omitted or abbreviated.

Some terms and definitions used in the description of the embodiments of the present disclosure are first explained below. The so-called “ground” refers to a reference conductive unit having a reference voltage of 0 V potential or the 0 V potential itself. The reference conductive unit may be a conductor formed of such as metal. The 0 V potential may also be referred to as a ground potential. In the embodiments of the present disclosure, a voltage expressed without a specifically configured reference represents a potential observed from a ground aspect.

For any transistor formed as a field-effect transistor (FET) including a metal-oxide-semiconductor field-effect transistor (MOSFET), an on state refers to a state of conduction between the drain and the source of the transistor, and an off state refers to a state of non-conduction (a state of disconnection) between the drain and the source of the transistor. The same applies to non-FET transistors. Unless otherwise specified, a MOSFET may be understood as an enhanced MOSFET. MOSFET is an abbreviation of metal-oxide-semiconductor field-effect transistor. Moreover, unless otherwise specified, in any MOSFET, it is considered that the back gate is shorted to the source.

Electrical characteristics of a MOSFET include a gate threshold voltage. For any transistor serving as an N-channel and enhanced MOSFET, the gate potential of the transistor is higher than the source potential of the transistor, and when the size of the voltage between the gate and the source (the gate potential observed from the source potential) of the transistor is more than the gate threshold voltage of the transistor, the transistor becomes in an on state, otherwise the transistor becomes in an off state. For any transistor serving as a P-channel and enhanced MOSFET, the gate potential of the transistor is lower than the source potential of the transistor, and when the size of the voltage between the gate and the source (the gate potential observed from the source potential) of the transistor is more than the gate threshold voltage of the transistor, the transistor becomes in an on state, otherwise the transistor becomes in an off state. For any FET, the gate threshold voltage is defined as the voltage between the gate and the source needed to flow a drain current of a predetermined size when a predetermined voltage is applied between the drain and source of the FET in an environment with a predetermined ambient temperature.

In the description below, for any transistor, the on state and the off state is sometimes expressed simply as on and off. A connection formed between multiple parts of a circuit, such as circuit elements, wires and nodes that form a circuit, refers to an electrical connection unless otherwise specified.

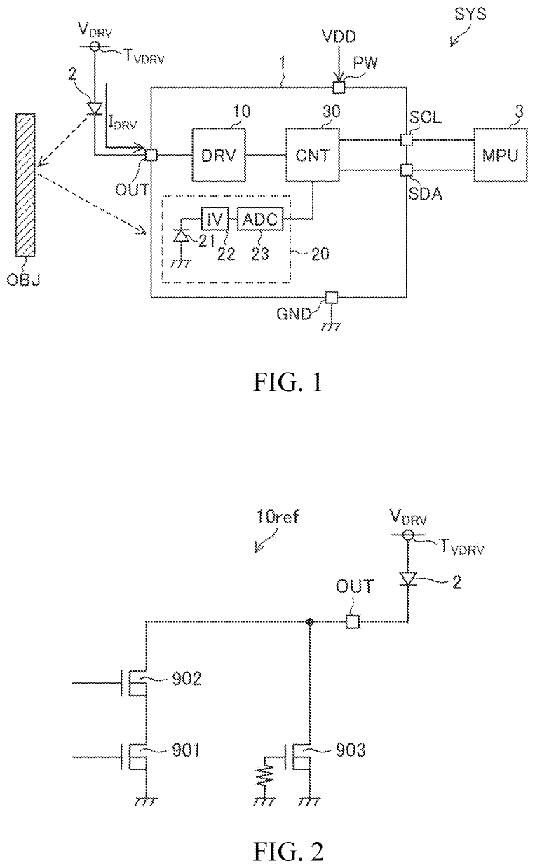

FIG. 1 shows an overall configuration diagram of a sensor system SYS according to an embodiment of the present disclosure. The sensor system SYS includes a semiconductor device 1, a load 2 and a micro processing unit (MPU) 3.

The semiconductor device 1 is an electronic component including the following parts: a semiconductor chip, having a semiconductor integrated circuit formed on a semiconductor substrate; a housing (a package), accommodating the semiconductor chip; and a plurality of external terminals, exposed outside the semiconductor device 1 from the housing. The semiconductor device 1 is formed by packaging the semiconductor chip in the housing (package) formed of resin. In FIG. 1, although a power terminal PW, a ground terminal GND, an output terminal OUT, and communication terminals SCL and SDA serve as a part of multiple external terminals, other external terminals may also be disposed at the semiconductor device 1.

The load 2 is a light emitting device that receives a supply of a drive current I_{DRV} and thus emits light. Thus, the load 2 is primarily referred to as a light emitting device 2 below. The light emitting device 2 may be implemented by a light emitting diode (LED) or a semiconductor laser. The semiconductor laser may be, for example, a vertical cavity surface emitting laser (VCSEL). The light emitting device 2 has a first terminal and a second terminal, wherein the first terminal of the light emitting device 2 is connected to a terminal T_{VDRV} to which a drive voltage V_{DRV} is applied. The second terminal of the light emitting device 2 is connected to the output terminal OUT. The light emitting device 2 emits light as the drive current I_{DRV} flows from the first terminal to the second terminal of the light emitting device 2. For example, if the light emitting device 2 is an LED, the anode of the LED is connected to the terminal T_{VDRV}, and the cathode of the LED is connected to the output terminal OUT. The wavelength of light emitted from the light emitting device 2 may be any as desired. The light emitted from the light emitting device 2 may be visible light or may be infrared light.

The semiconductor device 1 and the light emitting device 2 form a proximity sensor. However, it may also be understood that the MPU 3 is also included as a constituent of the proximity sensor. The semiconductor device 1 includes a drive circuit 10, a light receiving circuit 20 and a control circuit 30. The drive circuit 10 is connected to the output terminal OUT, and supplies the drive current I_{DRV} to the light emitting device 2 at necessary timings under the control of the control circuit 30. The light emitted from the light emitting device 2 is reflected by an object OBJ. Reflected light from the object OBJ is received by the light receiving circuit 20, and this means that a signal of a light receiving result (hereinafter referred to as a light receiving result signal) is output from the light receiving circuit 20 to the control circuit 30.

The light receiving circuit 20 includes a light receiving element 21, an IV conversion circuit 22 and an analog-to-digital converter (ADC) 23. The light receiving element 21 receives the reflected light from the object OJB, and generates a current corresponding to a light receiving intensity of the reflected light. The light receiving element 21 may be formed by a photodiode or a phototransistor. The IV conversion circuit 22 converts the current generated by the light receiving element 21 into a voltage, and outputs the voltage obtained from the conversion. The output voltage of the IV conversion circuit 22 increases as the light receiving intensity of the light receiving element 21 increases. The output voltage of the IV conversion circuit 22 is an analog voltage. The ADC 23 is an analog-to-digital conversion circuit, and performs an analog-to-digital conversion of converting the output voltage of the IV conversion circuit 22 into a digital signal. The digital signal obtained from the analog-to-digital conversion is used as the light receiving result signal, and is output from the light receiving circuit 20 to the control circuit 30. Moreover, given that the light receiving result signal can be obtained, variations may be made to the configuration of the light receiving circuit 20.

The control circuit 30 is connected to the MPU 3 through the communication terminals SCL and SDA, and bi-directionally communicates with the MPU 3 through the communication terminals SCL and SDA. The control circuit 30 includes an interface circuit for implementing the bi-directional communication with the MPU 3. Herein, the bi-directional communication between the control circuit 30 and the MPU 3 is implemented according to 2-wire serial communications of the I²C specification as an example. However, given that the bi-directional communication between the control circuit 30 and the MPU 3 can be achieved, the connection means and communication means between the control circuit 30 and the MPU 3 can be any as desired. The control circuit 30 is capable of controlling states of the drive circuit 10 based on a command received from the MPU 3. The control on the states of the drive circuit 10 includes control on the size of the drive current I_{DRV}, and control of whether to supply the drive current I_{DRV} to the light emitting device 2. Moreover, the control circuit 30 is capable of sending the light receiving result signal from the light receiving circuit 20 or a signal based on the light receiving result signal to the MPU 3.

A power supply voltage VDD is fundamentally supplied to the power terminal PW. Although the power supply voltage VDD supplied to the power terminal PW may be interrupted in some cases, the power supply voltage VDD is supplied to the power terminal PW unless otherwise specified. Respective circuits in the semiconductor device 1 are driven based on the power supply voltage VDD. A ground terminal GND is connected to a ground. The power supply voltage VDD and the drive voltage V_{DRV} are positive direct-current (DC) voltages. However, the drive voltage V_{DRV} is higher than the power supply voltage VDD.

In the aim of reducing power consumption, the power supply voltage VDD of the semiconductor device 1 used by an ultrasonic sensor is usually set to be lower. Accordingly, considering the characteristics of the light emitting device 2, the drive voltage V_{DRV} of the light emitting device 2 is usually set to be higher than the power supply voltage VDD. For example, the power supply voltage VDD is set to be a voltage equal to or more than 1.7 V and equal to or less than 3.6 V, and the drive voltage V_{DRV} is set to be a voltage of equal to or more than 3.8 V and equal to or less than 4.5 V.

Based on the size of the power supply voltage VDD, a breakdown voltage of each MOSFET in the semiconductor device 1 can be set. In this embodiment, for more specific description, the semiconductor device 1 is formed by using a MOSFET having a 3 V breakdown voltage.

FIG. 2 shows a circuit diagram of a drive circuit 10ref of a reference configuration. The drive circuit 10ref includes a transistor 901 functioning as an output side element of a current mirror circuit, a switch transistor 902 setting a state of conduction or non-conduction between the output terminal OUT and the transistor 901, and a transistor 903 for electrostatic protection. The transistors 901 to 903 are N-channel MOSFETs. When the transistor 902 is arranged at a high potential side of the transistor 901, the transistors 901 and 902 are directly connected between the output terminal OUT and the ground. By turning on the transistor 902, a current set by the current mirror circuit flows through the light emitting device 2 and the transistors 901 and 902.

In the drive circuit 10ref in FIG. 2, if the drive voltage V_{DRV} is equal to or more than 3.8 V and equal to or less than 4.5 V, a voltage exceeding 3 V is applied all the time or applied at specific timings between the electrodes of each of the transistors 901 to 903. Thus, in the drive circuit 10ref, MOSFETs having a 5 V breakdown voltage are used as the transistors (901 to 903). If the drive circuit 10ref is used as the drive circuit 10 of the semiconductor device 1, both of MOSFETs having a 3 V breakdown voltage and MOSFETs having a 5 V breakdown voltage need to be formed at a semiconductor substrate. This increases the types of masks in course of manufacturing the semiconductor device 1 and is associated with increased costs. Moreover, the increase in the breakdown voltage of the transistors causes an increase in the size of the transistors.

In this embodiment, by adopting the following configuration, MOSFETs having a 5 V breakdown voltage are not required and the drive circuit 10 is formed by MOSFETs having a 3 V breakdown voltage. As a result, the entirety of the semiconductor device 1 can be formed by MOSFETs having a 3 V breakdown voltage without involving any MOSFETs having a 5 V breakdown voltage.

Moreover, a MOSFET having a 3 V breakdown voltage refers to a MOSFET in which a breakdown voltage between electrodes is 3 V, and a MOSFET having a 5 V breakdown voltage refers to a MOSFET in which a breakdown voltage between electrodes is 5 V. There are six breakdown voltages as the breakdown voltage between electrodes. The six breakdown voltages include gate-source breakdown voltage, gate-drain breakdown voltage, drain-source breakdown voltage, drain-back gate breakdown voltage, source-back gate breakdown voltage, and gate-back gate breakdown voltage. In a MOSFET having a 3 V breakdown voltage, the sizes of the six voltages between electrodes all need to be used below 3 V. The six voltages between electrodes include gate-source voltage, gate-drain voltage, drain-source voltage, drain-back gate voltage, source-back gate voltage, and gate-back gate voltage. The same applies to MOSFETs having a 5 V breakdown voltage.

In the multiple embodiments below, some specific configuration examples, operation examples, application techniques and variation techniques associated with the sensor system SYS (more particularly, the drive circuit 10) are described. Unless otherwise specified and without any contradiction, the items enumerated in this embodiment are applicable to the various embodiments below. In the various embodiments, the description of the embodiments can be considered as overruling in case of any items contradictory to the items described above. Provided there are not contradictions, the items described in any one of the embodiments below are also applicable to any embodiment (that is to say, any two or more of the embodiments can be combined).

### First Embodiment

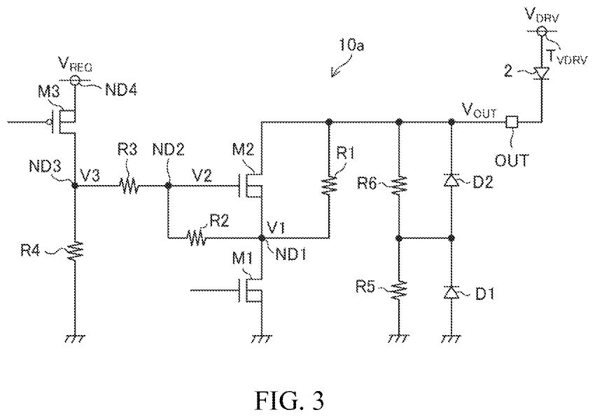

A first embodiment is described. FIG. 3 shows a diagram of a drive circuit 10a of the first embodiment. The drive circuit 10a can be used as the drive circuit 10 in FIG. 1. The drive circuit 10a includes transistors M1 to M3, resistors R1 to R6, and diodes D1 and D2. The transistors M1 and M2 are N-channel MOSFETs, and the transistor M3 is a P-channel MOSFET. In the first embodiment, the drive voltage V_{DRV} is set to be a voltage equal to or more than 3.8 V and equal to or less than 4.5 V. All of the transistors M1 to M3 are MOSFETs having a 3 V breakdown voltage. Moreover, a voltage applied to the output terminal OUT is referred to as an output terminal voltage V_{OUT}. The control circuit 30 controls on and off of the transistors M1 to M3 by directly or indirectly controlling gate potentials of the transistors M1 to M3.

The output terminal OUT is connected to the drain of the transistor M2 and a first terminal of the resistor R1. The source of the transistor M2 and a second terminal of the resistor R1 are connected to a node ND1. The drain of the transistor M1 and a first terminal of the resistor R2 are connected to the node ND1. The source of the transistor M1 is connected to the ground. The gate of the transistor M2 and a second terminal of the resistor R2 are connected to a node ND2. A first terminal of the resistor R3 is connected to the node ND2, and a second terminal of the resistor R3 is connected to a node ND3. The drain of the transistor M3 and a first terminal of the resistor R4 are connected to the node ND3. A second terminal of the resistor R4 is connected to the ground. The source of the transistor M3 is connected to a node ND4. Voltages at the nodes ND1, ND2 and ND3 are referred to as voltages V1, V2 and V3 in the description below, respectively.

The anode of the diode D1 is connected to the ground. The cathode of the diode D1 is connected to the anode of the diode D2, and the cathode of the diode D2 is connected to the output terminal OUT. A first terminal of the resistor R6 is connected to the output terminal OUT. A second terminal of the resistor R6 and a first terminal of the resistor R5 are connected to the cathode of the diode D1 and the anode of the diode D2. A second terminal of the resistor R5 is connected to the ground. A predetermined internal voltage V_{REG} is applied to the node N4. The internal voltage V_{REG} is a positive DC voltage based on the power supply voltage VDD and generated inside the semiconductor device 1. The internal voltage V_{REG} is less than the drive voltage V_{DRV} and is also less than the breakdown voltages (3 V) of the transistors M1 to M3.

The transistor M1 is a drive transistor that determines the size of the drive current I_{DRV}. A current mirror circuit is formed by the transistor M1 and one or more of other MOSFETs, when the transistor M2 is turned on, a current with a size determined by the current mirror circuit serves as the drive current I_{DRV} and flows between the drain and the source of the transistor M1.

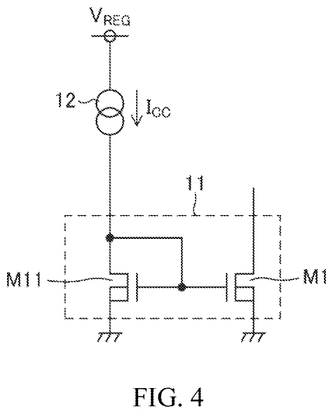

For example, a current mirror circuit 11 and a constant current source 12 shown in FIG. 4 may be arranged in advance in the drive circuit 10a. The current mirror circuit 11 includes N-channel MOSFETs, that is, a transistor M11 and the transistor M1. The constant current source 12 is driven based on the internal voltage V_{REG}, and generates a constant current I_{CC} that flows from a terminal to which the internal voltage V_{REG} is applied to the drain of the transistor M11. The drain and the gate of the transistor M11 are commonly connected to the gate of the transistor M1. The source of the transistor M11 is connected to the ground. The MOSFETs included in each of the transistor M11 and the constant current source 12 are all MOSFETs having a 3 V breakdown voltage. When the transistor M2 is turned on, a current proportional to the drain current (that is, the constant current I_{CC}) of the transistor M11 flows as the drain current of the transistor M1, and the drain current of the transistor M1 flows as the drive current I_{DRV} to the light emitting device 2.

The control circuit 30 is capable of controlling the constant current source 12 to an active or a non-active state. When the constant current source 12 is in an active state, as described above, the constant current source 12 generates the constant current I_{CC} that flows from the terminal to which the internal voltage V_{REG} is applied to the drain of the transistor M11. As a result, the transistor M1 is turned on when the constant current source 12 is in an active state. In the non-active state of the constant current source 12, the constant current source 12 does not generate the constant current I_{CC}. In the non-active state of the constant current source 12, the gate voltage of the transistor M1 becomes 0 V through a pull-down resistor (not shown) arranged between the gate of the transistor M1 and the ground. As a result, the transistor M1 is turned off when the constant current source 12 is in the non-active state. As such, the control circuit 30 controls the gate potential of the transistor M1 through the state of the constant current source 12, accordingly turning on or turning off the transistor M1. However, the control means of the control circuit 30 for the gate potential of the transistor M1 can be any as desired, and the control circuit 30 may also directly control the gate potential of the transistor M1. For more specific description below, the transistor M1 is controlled to be turned on and turned off by controlling the constant current source 12 to be in the active state and the non-active state.

The transistor M2 is a switch transistor for setting conduction or non-conduction between the output terminal OUT and the transistor M1.

The transistor M3 is a control transistor for turning on and turning off the transistor M2. The gate potential of the transistor M3 is controlled by the control circuit 30.

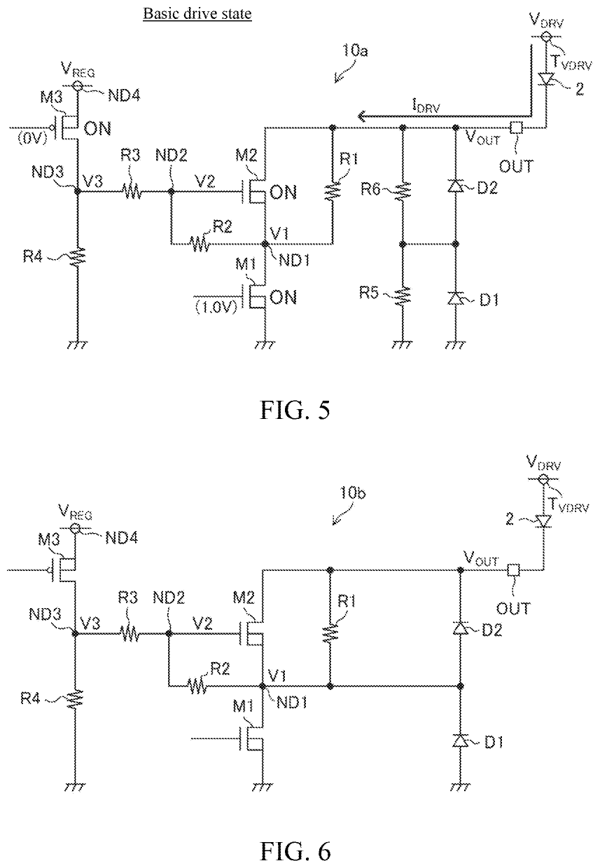

FIG. 5 shows conditions of the drive circuit 10a in a basic drive state. In the basic drive state, the transistor M3 is turned on by setting the gate potential of the transistor M3 to be sufficiently low and, moreover, the transistor M1 is turned on by setting the constant current source 12 to be in the active state. More specifically, for example, in the basic drive state, the gate potential of the transistor M3 is set to be 0 V; as a result, the size of the voltage between the gate and the source of the transistor M3 exceeds the gate threshold voltage of the transistor M3 such that the transistor M3 is turned on. Moreover, for example, in the basic drive state, the control circuit 30 controls the constant current source 12 to be in the active state, and the gate potential of the transistor M1 becomes more than the gate threshold voltage of the transistor M1 by 1 V; as a result, the transistor M1 is turned on.

By turning on the transistor M3, a current flows from the node ND4 through the transistor M3, the resistor R3, the resistor R2 and the transistor M1; as a result, the voltage V2 that sets the node ND1 as a low potential side is generated in the resistor R2. That is to say, a voltage drop that holds “V2>V1” true is generated in the resistor R2, and by controlling the voltage drop generated in the resistor R2 to exceed the gate threshold voltage of the transistor M2, the transistor M2 is turned on.

As such, the control circuit 30 controls the transistors M1 and M3 to be on in the basic drive state, and as a result, the voltage drop generated in the resistor R2 turns on the transistor M2. When the transistor M2 is turned on, the output terminal OUT is conducted to the drain of the transistor M1. As a result, the drive current I_{DRV} that flows from the terminal T_{VDRV} through the light emitting device 2, the output terminal OUT, the channel (between the drain and the source) of the transistor M2, the channel (between the drain and the source) of the transistor M1 to the ground, and hence the light emitting device 2 emits light.

It can be understood from the circuit configuration in FIG. 3 that, in the drive circuit 10a, the output terminal voltage V_{OUT} is divided by using multiple resistors (R1 to R4), the node ND1 (hence the source of the transistor M2 and the drain of the transistor M1) is biased by the voltage V1 obtained from the dividing, and the node ND2 (hence the gate of the transistor M2) is biased by the voltage V2 obtained from the dividing. Thus, by appropriately setting resistance values of the resistors, the voltages between the electrodes of each of the transistors M1 to M3 are all suppressed to be equal to or less than 3 V. Therefore, the transistors M1 to M3 can be implemented by MOSFETs having a 3 V breakdown voltage.

On the other hand, the diodes D1 and D2 are electrostatic protection elements, and an electrostatic protection circuit is formed by the diodes D1 and D2. It can also be understood as that the resistors R6 and R7 are also constituents of the electrostatic protection circuit. When the output terminal OUT is in an open state, sometimes an instantaneous overvoltage such as static electricity (hereinafter referred to as an electrostatic discharge (ESD) pulse) is applied to the output terminal OUT. When an ESD pulse is applied to the output terminal OUT, the voltage at the output terminal OUT exceeds a sum of the reverse breakdown voltage of the diode D1 and the reverse breakdown voltage of the diode D2, and so the current of the ESD pulse flows through the diodes D2 and D1 to the ground, and a protection target circuit is protected from the ESD pulse. The protection target circuit is a circuit including the transistors M1 to M3 and the resistors R1 to R4, and the electrostatic protection circuit is arranged at a position closer to the output terminal OUT than the protection target circuit (particularly the transistors M1 and M2).

It can be understood from the circuit configuration in FIG. 3 that, in the drive circuit 10a, the output terminal voltage V_{OUT} is divided by using multiple resistors (R5 and R6), and a connection node between the diodes D1 and D2 is biased by the voltage obtained from the dividing. Thus, by appropriately setting resistance values of the resistors, the voltage between the electrodes (the voltage between the anode and the cathode) of each of the diodes D1 and D2 is suppressed to be equal to or less than 3 V.

### Second Embodiment

A second embodiment is described. The drive circuit 10a in FIG. 3 can be modified into a drive circuit 10b in FIG. 6. The drive circuit 10b of the second embodiment can be used as the drive circuit 10 in FIG. 1. In the drive circuit 10a, modifications of a first circuit in which the resistors R5 and R6 are deleted and a second circuit in which the cathode of the diode D1 and the anode of the diode D2 are connected to the node ND1 are implemented, so as to obtain the drive circuit 10b. In addition to the modifications of the first circuit and the second circuit, the drive circuit 10b has a configuration the same as that of the drive circuit 10a, and operations of the second embodiment are the same as the operations of the first embodiment.

The resistor R6 in the drive circuit 10a in FIG. 3 is replaced by the resistor R1 in the drive circuit 10b in FIG. 6, and the resistor R5 in the drive circuit 10a in FIG. 3 is replaced by the resistors R2 to R4 in the drive circuit 10b in FIG. 6. In the second embodiment, the electrostatic protection circuit (D1, D2) is also arranged at a position closer to the output terminal OUT than the protection target circuit (particularly the transistors M1 and M2).

### Third Embodiment

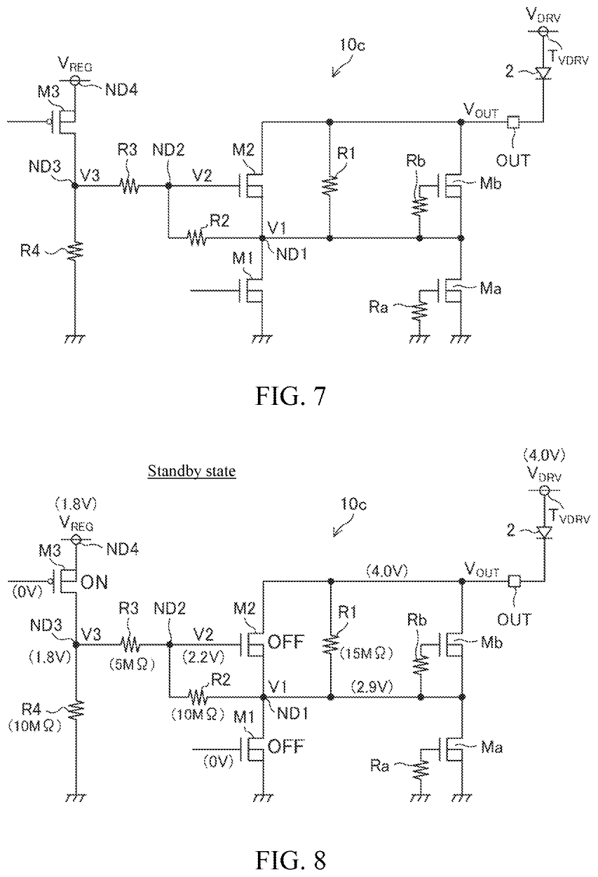

A third embodiment is described. The drive circuit 10a in FIG. 3 can be modified into a drive circuit 10c in FIG. 7. The drive circuit 10c of the third embodiment can be used as the drive circuit 10 in FIG. 1. In the drive circuit 10a, modifications of a third circuit in which the diodes D1 and D2 and the resistors R5 and R6 are replaced by transistors Ma and Mb and resistors Ra and Rb are implemented, so as to obtain the drive circuit 10c. In addition to the modifications of the third circuit, the drive circuit 10c has a configuration the same as that of the drive circuit 10a, and operations of the third embodiment are the same as the operations of the first embodiment. However, accompanied with an application of the modifications of the third circuit, the node ND1 in the drive circuit 10c is connected to the transistors Ma and Mb and the resistor Rb.

More specifically, the transistors Ma and Mb are N-channel MOSFETs. The transistors Ma and Mb are MOSFETs having a 3 V breakdown voltage the same as the transistors M1 to M3. The drain of the transistor Mb is connected to the output terminal OUT. The source of the transistor Mb and the drain of the transistor Ma are connected to the node ND1. The source of the transistor Ma is connected to the ground. The resistor Ra is connected between the gate and the source of the transistor Ma. That is to say, a first terminal of the resistor Ra is connected to the gate of the transistor Ma, and a second terminal of the resistor Ra is connected to the source of the transistor Ma (hence connected to the ground). The resistor Rb is connected between the gate and the source of the transistor Mb. That is to say, a first terminal of the resistor Rb is connected to the gate of the transistor Mb, and a second terminal of the resistor Rb is connected to the source of the transistor Mb (hence connected to the node ND1). Between the drain and the source of the transistor Ma, a parasitic diode is added (the conditions of the adding are not shown) in a forward direction in a direction from the source to the drain. Between the drain and the source of the transistor Mb, a parasitic diode is added (the conditions of the adding are not shown) in a forward direction in a direction from the source to the drain.

The transistors Ma and Mb are electrostatic protection elements, and an electrostatic protection circuit is formed by the transistors Ma and Mb. It can also be understood as that the resistors Ra and Rb are also constituents of the electrostatic protection circuit. When an ESD pulse is applied to the output terminal OUT, the voltage at the output terminal OUT exceeds a sum of the reverse breakdown voltage of the parasitic diode of the transistor Mb and the reverse breakdown voltage of the parasitic diode of the transistor Ma, and so the current of the ESD pulse flows through the parasitic diodes to the ground, and a protection target circuit is protected from the ESD pulse. In the third embodiment, the electrostatic protection circuit (Ma, Mb) is also arranged at a position closer to the output terminal OUT than the protection target circuit (particularly the transistors M1 and M2).

It can be understood from the circuit configuration in FIG. 7 that, in the drive circuit 10c, the output terminal voltage V_{OUT} is divided by using multiple resistors (R1 to R4), and a connection node between the transistors Ma and Mb is biased by the voltage obtained from the dividing. Thus, by appropriately setting resistance values of the resistors, the voltages between the electrodes of each of the transistors Ma and Mb are all suppressed to be equal to or less than 3 V. Therefore, the transistors Ma and Mb can be implemented by MOSFETs having a 3 V breakdown voltage.

### Fourth Embodiment

A fourth embodiment is described. In the fourth embodiment, taking the configuration of the drive circuit 10c of the third embodiment for example, specific examples of voltage values of the drive circuit 10c in various states are provided below. Moreover, in the fourth embodiment, the size of the gate threshold voltages of the transistors M1 to M3 is set to be 0.5 V. In addition, in the fourth embodiment, the drive voltage V_{DRV} is set to be 4.0 V, and the resistance values of the resistors R1, R2, R3 and R4 are set to be 15 MΩ, 10 MΩ, 5 MΩ and 10 MΩ (referring to FIG. 8 to FIG. 11), respectively. As described above, the transistors M1 to M3, Ma and Mb are MOSFETs having a 3 V breakdown voltage. Thus, the drive voltage V_{DRV} (4.0 V) is more than the breakdown voltages of the transistors M1 to M3, Ma and Mb.

The states of the semiconductor device 1 are substantially categorized into a power-on state in which the power supply voltage VDD is supplied to the power terminal PW, and a power interrupted state in which the power supply voltage VDD is disconnected from the power terminal PW. In the power interrupted state, the potential of the power terminal PW is 0 V. In any of the power-on state and power interrupted state, the drive voltage V_{DRV} is kept at 4.0 V. In the power-on state, the control circuit 30 is capable of setting the state of the drive circuit 10c to any of a standby state, a basic drive state and a power-off state.

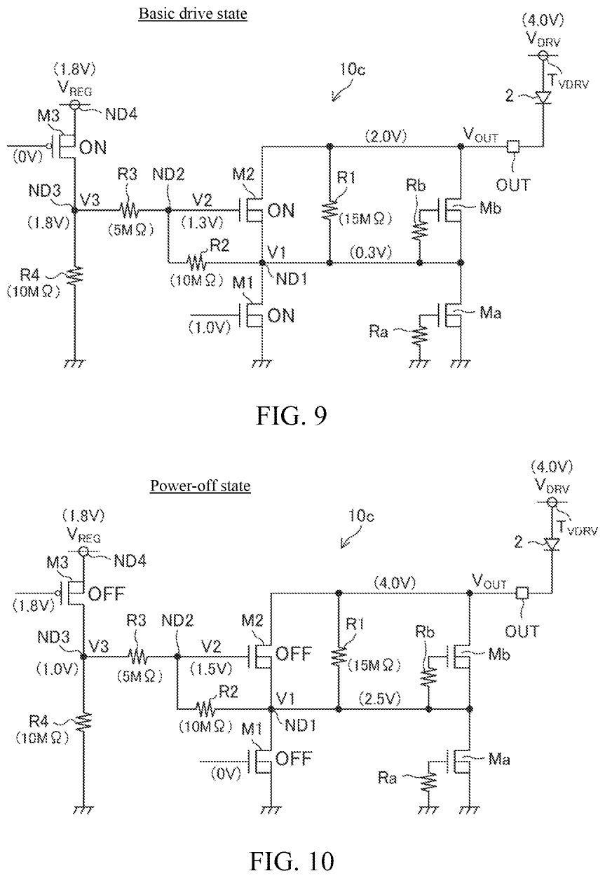

FIG. 8, FIG. 9 and FIG. 10 show conditions of the drive circuit 10c in the standby state, the basic drive state and the power-off state, respectively. In the power-on state, a circuit operation of generating the internal voltage V_{REG} of the semiconductor device 1 takes place to apply the internal voltage V_{REG} to the node ND4. In the standby state, the basic drive state and the power-off state, the interval voltage V_{REG} is 1.8 V.

The standby state in FIG. 8 is a state in which the drive current I_{DRV} is going to be supplied to the light emitting device 2. In the standby state, the gate potential of the transistor M3 is set to be 0 V by the control circuit 30, and the transistor M3 is turned on. Moreover, in the standby state, the constant current source 12 (referring to FIG. 4) is set to be in the non-active state by the control circuit 30, the gate potential of the transistor is set to be 0 V, and the transistor M1 is turned off. Thus, the voltage V3 becomes 1.8 V through the transistor M3 that is turned on; on the other hand, a minute current flows from the output terminal OUT through a series circuit of the resistors R1 to R3, and the voltages V1 and V2 are determined via the minute current. Although the minute current flows from the terminal T_{VDRV} through the light emitting device 2, such current is an extremely small current instead of the drive current I_{DRV}, and so the light emitting device 2 does not emit light (or the amount of light emitted can be omitted). Moreover, the voltage drop in the light emitting device 2 caused by this minute current is also omitted.

Thus, in the standby state, the output terminal voltage V_{OUT} becomes 4.0 V, and the voltages V1 and V2 are approximately 2.9 V and 2.2 V, respectively. In the standby state, since “V2<V1”, the transistor M2 is turned off. Thus, it is learned that, in the standby state, the voltages between the electrodes of each of the transistors M1 to M3. Ma and Mb are all suppressed to be equal to or less than the breakdown voltage (equal to or less than 3 V).

The basic drive state in FIG. 9 is a state in which the drive current I_{DRV} is supplied to the light emitting device 2. In the basic drive state, the gate potential of the transistor M3 is set to be 0 V by the control circuit 30, and the transistor M3 is turned on. Moreover, in the basic drive state, the constant current source 12 (referring to FIG. 4) is set to be in the active state by the control circuit 30, the gate potential of the transistor becomes 1.0 V, and the transistor M1 is turned on. With the transistor M3 that is turned on, the voltage V3 becomes 1.8 V; on the other hand, with a current flowing from the node ND4 through the transistor M3, the resistor R3, the resistor R2 and the transistor M1, the voltage V2 becomes approximately 1.3 V and the voltage V1 becomes approximately 0.3 V. As a result, the transistor M2 is turned on.

Thus, the drive current I_{DRV} proportional to the constant current I_{CC} (referring to FIG. 4) flow from the terminal T_{VDRV} through the light emitting device 2, the output terminal OUT, the transistor M2 and the transistor M1, and the light emitting device 2 emits light. At this point in time, the voltage drop of the light emitting device 2 is set to be approximately 2.0 V. As a result, the output terminal voltage V_{OUT} in the basic drive state is approximately 2.0 V. Thus, it is learned that, in the basic drive state, the voltages between the electrodes of each of the transistors M1 to M3, Ma and Mb are all suppressed to be equal to or less than the breakdown voltage (equal to or less than 3 V).

The power-off state in FIG. 10 is a state in which the drive current I_{DRV} is not supplied to the light emitting device 2 and the overall power consumption of the semiconductor device 1 is minimized as much as possible. In the power-off state, the gate potential of the transistor M3 is set to be 1.8 V by the control circuit 30, and the transistor M3 is turned off. Moreover, in the power-off state, the constant current source 12 (referring to FIG. 4) is set to be in a non-active state by the control circuit 30, the gate potential of the transistor is set to be 0 V, and the transistor M1 is turned off. Thus, a minute current flows from the output terminal OUT through a series circuit of the resistors R1 to R4, and the voltages V1 to V3 are determined via the minute current. Although the minute current flows from the terminal T_{VDRV} through the light emitting device 2, such current is an extremely small current instead of the drive current I_{DRV}, and so the light emitting device 2 does not emit light (or the amount of light emitted can be omitted). Moreover, the voltage drop in the light emitting device 2 caused by this minute current is also omitted.

Thus, in the power-off state, the output terminal voltage Vou-r becomes 4.0 V, and the voltages V1, V2 and V3 are 2.5 V, 1.5 V and 1.0 V, respectively. In the power-off state, since “V2<V1”, the transistor M2 is turned off. Thus, it is learned that, in the power-off state, the voltages between the electrodes of each of the transistors M1 to M3, Ma and Mb are all suppressed to be equal to or less than the breakdown voltage (equal to or less than 3 V).

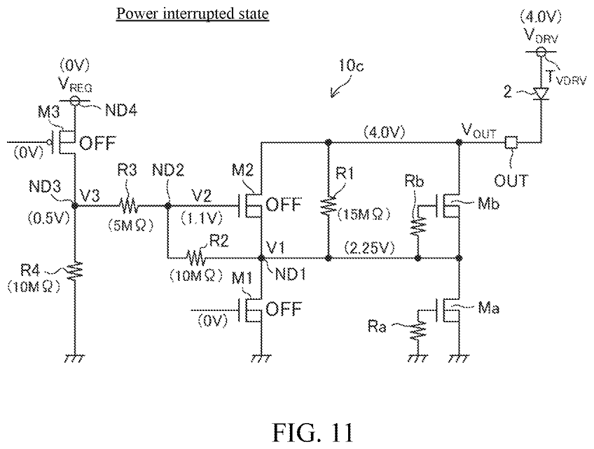

FIG. 11 shows conditions of the drive circuit 10c in the power interrupted state. In the power interrupted state, circuits in the semiconductor device 1 including the control circuit 30 do not operate. Thus, in the power interrupted state, the potential at the node ND4 is 0 V, the gate potential of each of the transistors M1 and M3 is also 0 V, and so the transistors M1 and M3 are turned off. However, in the power interrupted state in FIG. 11, by applying the 4.0 V drive voltage V_{DRV} to the terminal T_{VDRV}, the 4.0 V drive voltage V_{DRV} is also applied to the output terminal OUT. Thus, in the power interrupted state in FIG. 11, a circuit from the output terminal OUT through the resistors R1 to R3 and the resistor R4 to the ground, and a circuit through the parasitic diode of the transistor M3 to the node ND4 are formed. The minute current flows through these two circuits, and the voltages V1 to V3 are determined through this minute current. Although the minute current flows from the terminal T_{VDRV} through the light emitting device 2, such current is an extremely small current instead of the drive current I_{DRV}, and so the light emitting device 2 does not emit light (or the amount of light emitted can be omitted). Moreover, the voltage drop in the light emitting device 2 caused by this minute current is also omitted.

Thus, in the power interrupted state, the output terminal voltage V_{OUT} becomes 4.0 V, and the voltages V1, V2 and V3 are also dependent on the characteristics of the parasitic diode of the transistor M3 and are, for example, approximately 2.25 V, 1.1 V and 0.5 V, respectively. In the power interrupted state, since “V2<V1”, the transistor M2 is turned off. Thus, it is learned that, in the power interrupted state, the voltages between the electrodes of each of the transistors M1 to M3, Ma and Mb are all suppressed to be equal to or less than 3 V.

### Fifth Embodiment

A fifth embodiment is described. In the fifth embodiment, variation techniques of the items and supplementary items are described.

It can be considered that, in the drive circuit 10 and the control circuit 30 of this embodiment, a current driver that supplies the drive current I_{DRV} to the load 2 is formed. In the described example, the current driver is applied to a proximity sensor.

However, the object of application of the current driver of the present disclosure is not limited to a proximity sensor. The light emitting device serving as the load 2 may also be a light emitting element for illumination. The load 2 can be any, given that it is a load that implements any function with the current (I_{DRV}) supplied thereto.

The types of the channels of the field-effect transistors (FETs) shown in the embodiments are examples. Without compromising the form of the subject, any type of channels of FETs may be changed between P-type channels and N-type channels.

Given that no issues are incurred, any transistor may also be any type of transistor. For example, given that no issues are incurred, any transistor implemented by a MOSFET may be replaced by a junction FET, an insulated gate bipolar transistor (IGBT) or a bipolar transistor. Any transistor includes a first electrode, a second electrode and a control electrode. In an FET, one of the first and second electrodes is the drain and the other is the source, and the control electrode is the gate. In an IGBT, one of the first and second electrodes is the collector and the other is the emitter, and the control electrode is the gate. For a bipolar transistor that is not an IGBT, one of the first and second electrodes is the collector and the other is the emitter, and the control electrode is the base.

Various modifications may be appropriately made to the embodiments of the present disclosure within the scope of the technical concept of the claims. The embodiments above are only examples of possible implementations of the present disclosure, and the meanings of the terms of the present disclosure or the constituents are not limited to the meanings of the terms recited in the embodiments above. The specific numerical values used in the description are only examples, and these numerical values may be modified to other numerical values.

### Notes

A note is attached to the present disclosure to show specific configuration examples of the embodiments above.

According to an aspect of the present disclosure, a current driver is configured (as a first configuration) below. The current driver is configured to supply a drive current (I_{DRV}) to a load (2) disposed between a terminal (T_{VDRV}) to which a drive voltage (V_{DRV}) is applied and an output terminal (OUT), the current driver comprising: a first transistor (M1) and a second transistor (M2), connected in series between the output terminal and a ground; and a control circuit (30), configured to control states of the first transistor and the second transistor, wherein the first transistor is arranged at a potential side lower than the second transistor, the drive current is supplied to the load through the first transistor and the second transistor by turning on the first transistor and the second transistor, a first voltage (V1) and a second voltage (V2) are obtained by dividing an output terminal voltage applied to the output terminal using a plurality of resistors (R1 to R4), and a connection node between the first transistor and the second transistor and a control electrode of the second transistor are biased.

Thus, voltages between electrodes of each of the transistors can be suppressed to be a voltage less than the drive voltage. As a result, a current driver can be formed by transistors having a breakdown voltage less than the drive voltage.

The current driver of the first configuration may further be configured as (a second configuration), wherein the first transistor is disposed between the ground and a first node (ND1) corresponding to the connection node between the first transistor and the second transistor; the second transistor includes: a first electrode connected to the output terminal, a second electrode connected to the first node, and the control electrode connected to a second node (ND2); and the first voltage and the second voltage are generated at the first node and the second node by dividing the output terminal voltage using the plurality of resistors.

The current driver of the second configuration may further be configured as (a third configuration) further comprising: a third transistor (M3) disposed between a third node (ND3) and a fourth node (ND4) to which a predetermined voltage (V_{REG}) is to be applied; wherein the plurality of resistors include: a first resistor (R1) connected between the first electrode and the second electrode of the second transistor, a second resistor (R2) connected between the second electrode and the control electrode of the second transistor, a third resistor (R3) connected between the second node and the third node; and a fourth resistor (R4) connected between the third node and the ground.

Thus, voltages between electrodes of each of the transistors can be suppressed to be a voltage less than the drive voltage. As a result, a current driver can be formed by transistors having a breakdown voltage less than the drive voltage.

The current driver of the third configuration may further be configured as (a fourth configuration), wherein the control circuit turns on the first transistor and the third transistor and utilizes a voltage drop occurring in the second resistor to turn on the second transistor, thereby conducting the output terminal to the first transistor through the second transistor.

The current driver of the third or fourth configuration may further be configured as (a fifth configuration), wherein when a power supply voltage (VDD) is supplied to a device (1) including the current driver, the predetermined voltage is applied to the fourth node; the control circuit controls states of the first transistor and the second transistor to be any one of a first state (standby state), a second state (basic drive state) and a third state (power-off state); in the first state, the first transistor is off and the third transistor is on; in the second state, both the first transistor and the third transistor are turned on; in the third state, both the first transistor and the third transistor are turned off, the drive voltage is higher than breakdown voltages of the first to third transistors; and in any one of the first state to the third state, voltages between the electrodes of the first transistor to the third transistor are set to be equal to or less than the breakdown voltages by the plurality of resistors.

Accordingly, a current driver can be formed by transistors having a breakdown voltage less than the drive voltage.

The current driver of the fifth configuration may further be configured as (a sixth configuration), wherein in a fourth state (power interrupted state) that a ground potential is applied to the fourth node, the control electrode of the first transistor, and a control electrode of the third transistor, by interrupting a supply of the power supply voltage to the device, and when the drive voltage is applied to the output terminal, a voltage between the electrodes of each of the first to third transistors is set to be equal to or less than the breakdown voltages by the plurality of resistors.

Accordingly, a current driver can be formed by transistors having a breakdown voltage less than the drive voltage.

The current driver of any one of the first to sixth configurations may further be configured as (a seventh configuration) further comprising a first electrostatic protection element (D1 or Ma) and a second electrostatic protection element (D2 or Mb) connected in series between the output terminal and the ground, wherein the first electrostatic protection element is disposed at a potential side lower than the second electrostatic protection element, and a connection node (referring to FIG. 6 and FIG. 7) between the first electrostatic protection element and the second electrostatic protection element is biased by the first voltage or by a voltage obtained by dividing the output terminal voltage using other resistors (R5, R6) (referring to FIG. 3).

Accordingly, electrostatic protection elements having a breakdown voltage less than the drive voltage can be used in a current driver.

The current driver of the seventh configuration may further be configured as (an eighth configuration), wherein each of the electrostatic protection elements is a diode (D1. D2) having a forward direction from the ground to the output terminal, or a MOSFET (Ma, Mb) including a parasitic diode having the forward direction from the ground to the output terminal.

The current driver of any one of the first to eighth configurations may also be configured as (a ninth configuration), wherein the load is a light emitting device.

1. A current driver, configured to supply a drive current to a load disposed between a terminal to which a drive voltage is applied and an output terminal, the current driver comprising:
a first transistor and a second transistor, connected in series between the output terminal and a ground, and
a control circuit, configured to control states of the first transistor and the second transistor, wherein
the first transistor is arranged at a potential side lower than the second transistor,
the drive current is supplied to the load through the first transistor and the second transistor by turning on the first transistor and the second transistor,
a first voltage and a second voltage are obtained by dividing an output terminal voltage applied to the output terminal using a plurality of resistors, and
a connection node between the first transistor and the second transistor and a control electrode of the second transistor are biased.

2. The current driver of claim 1, wherein
the first transistor is disposed between the ground and a first node corresponding to the connection node between the first transistor and the second transistor,
the second transistor includes:
a first electrode connected to the output terminal;
a second electrode connected to the first node; and
the control electrode connected to a second node, and
the first voltage and the second voltage are generated at the first node and the second node by dividing the output terminal voltage using the plurality of resistors.

3. The current driver of claim 2, further comprising a third transistor disposed between a third node and a fourth node to which a predetermined voltage is to be applied, wherein
the plurality of resistors include:
a first resistor connected between the first electrode and the second electrode of the second transistor;
a second resistor connected between the second electrode and the control electrode of the second transistor;
a third resistor connected between the second node and the third node; and
a fourth resistor connected between the third node and the ground.

4. The current driver of claim 3, wherein the control circuit turns on the first transistor and the third transistor and utilizes a voltage drop occurring in the second resistor to turn on the second transistor, thereby conducting the output terminal to the first transistor through the second transistor.

5. The current driver of claim 3, wherein
when a power supply voltage is supplied to a device including the current driver, the predetermined voltage is applied to the fourth node,
the control circuit controls states of the first transistor and the second transistor to be any one of a first state, a second state and a third state,
in the first state, the first transistor is off and the third transistor is on,
in the second state, both the first transistor and the third transistor are turned on,
in the third state, both the first transistor and the third transistor are turned off,
the drive voltage is higher than breakdown voltages of the first to third transistors, and
in any one of the first state to the third state, voltages between the electrodes of the first transistor to the third transistor are set to be equal to or less than the breakdown voltages by the plurality of resistors.

6. The current driver of claim 5, wherein in a fourth state that a ground potential is applied to the fourth node, the control electrode of the first transistor, and a control electrode of the third transistor, by interrupting a supply of the power supply voltage to the device, and when the drive voltage is applied to the output terminal, a voltage between the electrodes of each of the first to third transistors is set to be equal to or less than the breakdown voltages by the plurality of resistors.

7. The current driver of claim 1, further comprising a first electrostatic protection element and a second electrostatic protection element connected in series between the output terminal and the ground, wherein
the first electrostatic protection element is disposed at a potential side lower than the second electrostatic protection element, and
a connection node between the first electrostatic protection element and the second electrostatic protection element is biased by the first voltage or by a voltage obtained by dividing the output terminal voltage using other resistors.

8. The current driver of claim 2, further comprising a first electrostatic protection element and a second electrostatic protection element connected in series between the output terminal and the ground, wherein
the first electrostatic protection element is disposed at a potential side lower than the second electrostatic protection element, and
a connection node between the first electrostatic protection element and the second electrostatic protection element is biased by the first voltage or by a voltage obtained by dividing the output terminal voltage using other resistors.

9. The current driver of claim 3, further comprising a first electrostatic protection element and a second electrostatic protection element connected in series between the output terminal and the ground, wherein
the first electrostatic protection element is disposed at a potential side lower than the second electrostatic protection element, and
a connection node between the first electrostatic protection element and the second electrostatic protection element is biased by the first voltage or by a voltage obtained by dividing the output terminal voltage using other resistors.

10. The current driver of claim 4, further comprising a first electrostatic protection element and a second electrostatic protection element connected in series between the output terminal and the ground, wherein
the first electrostatic protection element is disposed at a potential side lower than the second electrostatic protection element, and
a connection node between the first electrostatic protection element and the second electrostatic protection element is biased by the first voltage or by a voltage obtained by dividing the output terminal voltage using other resistors.

11. The current driver of claim 5, further comprising a first electrostatic protection element and a second electrostatic protection element connected in series between the output terminal and the ground, wherein
the first electrostatic protection element is disposed at a potential side lower than the second electrostatic protection element, and
a connection node between the first electrostatic protection element and the second electrostatic protection element is biased by the first voltage or by a voltage obtained by dividing the output terminal voltage using other resistors.

12. The current driver of claim 6, further comprising a first electrostatic protection element and a second electrostatic protection element connected in series between the output terminal and the ground, wherein
the first electrostatic protection element is disposed at a potential side lower than the second electrostatic protection element, and
a connection node between the first electrostatic protection element and the second electrostatic protection element is biased by the first voltage or by a voltage obtained by dividing the output terminal voltage using other resistors.

13. The current driver of claim 7, wherein each of the electrostatic protection elements is
a diode having a forward direction from the ground to the output terminal, or
a MOSFET including a parasitic diode having the forward direction from the ground to the output terminal.

14. The current driver of claim 8, wherein each of the electrostatic protection elements is
a diode having a forward direction from the ground to the output terminal, or
a MOSFET including a parasitic diode having the forward direction from the ground to the output terminal.

15. The current driver of claim 1, wherein the load is a light emitting device.

16. The current driver of claim 2, wherein the load is a light emitting device.

17. The current driver of claim 3, wherein the load is a light emitting device.

18. The current driver of claim 4, wherein the load is a light emitting device.

19. The current driver of claim 5, wherein the load is a light emitting device.

20. The current driver of claim 6, wherein the load is a light emitting device.
